(19) United States
(12) Patent Application Publication
(10) Pub. No.: US 2025/0081758 A1
(43) Pub. Date: Mar. 6, 2025

(54) DISPLAY PANEL AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Cuicui LIANG, Beijing (CN); Li ZHU, Beijing (CN); Jianmin YE, Beijing (CN); Fei CHEN, Beijing (CN)

(21) Appl. No.: 18/726,429

(22) PCT Filed: Jul. 25, 2022
(86) PCT No.: PCT/CN2022/107691

§ 371 Date: Jul. 3, 2024

(51) Int. Cl. H10K 59/126; H10K 59/38; H10K 59/40; H10K 59/80

(52) U.S. Cl. CPC H10K 59/126; H10K 59/38; H10K 59/40; H10K 59/873

(57) ABSTRACT

A display panel, including: a base substrate; a light-emitting substrate, provided on a side of the base substrate, where the light-emitting substrate includes a plurality of sub-pixels; and a light-shielding layer group, provided on a side of the light-emitting substrate away from the base substrate, where the light-shielding layer group includes at least two light-shielding layers, a light-shielding layer includes a plurality of light-shielding portions, an orthographic projection of a light-shielding portion of each of the light-shielding layers on the base substrate at least partially overlaps with each other, and the orthographic projection of the light-shielding portion on the base substrate does not overlap with an orthographic projection of a sub-pixel on the base substrate.

### CROSS REFERENCE TO RELATED APPLICATIONS

The present disclosure is based upon International Application No. PCT/CN2022/107691, filed on Jul. 25, 2022, and the entire contents of which are incorporated herein by reference for all purpose.

### TECHNICAL FIELD

The present disclosure relates to the field of display technology, and in particular, to a display panel and a display apparatus.

### BACKGROUND

The organic light-emitting diode (OLED) display panel has become a mainstream development direction in the field of display technology because it has the advantages of self-luminous, high brightness, good image quality, low energy consumption or the like. The OLED display panel is widely applied to consumer electronic products such as mobile phones, wearing devices, vehicle-mounted devices or the like.

However, the current display panel has poor peep-proof performance.

It should be noted that the information disclosed in the background portion above is only used to enhance the understanding of the background of the present disclosure, and therefore may include information that does not constitute related art known to those of ordinary skill in the art.

### SUMMARY

An objective of the present disclosure is to overcome the shortcomings of the related art and provide a display panel and a display apparatus.

According to an aspect of the present disclosure, there is provided a display panel, including:
a base substrate;
a light-emitting substrate, provided on a side of the base substrate, wherein the light-emitting substrate includes a plurality of sub-pixels; and
a light-shielding layer group, provided on a side of the light-emitting substrate away from the base substrate, wherein the light-shielding layer group includes at least two light-shielding layers, a light-shielding layer includes a plurality of light-shielding portions, an orthographic projection of a light-shielding portion of each of the light-shielding layers on the base substrate at least partially overlaps with each other, and the orthographic projection of the light-shielding portion on the base substrate does not overlap with an orthographic projection of a sub-pixel on the base substrate.

In some embodiments of the present disclosure, a distance between two adjacent light-shielding layers increases as a distance between a light-shielding layer close to or far away from the base substrate and the base substrate increases.

In some embodiments of the present disclosure, the light-shielding portion is located on at least one side of the sub-pixel along a second direction, the second direction is a peep-proof direction, and the second direction is parallel to a surface of the base substrate close to the light-emitting substrate.

In some embodiments of the present disclosure, the plurality of sub-pixels include a first sub-pixel, a second sub-pixel, and a third sub-pixel with different colors; a plurality of first sub-pixels and a plurality of second sub-pixels are alternately arranged along a first direction to form a first pixel row, a plurality of third sub-pixels are arranged along the first direction to form a second pixel row, a plurality of first pixel rows and a plurality of second pixel rows are alternately arranged along the second direction, and a gap is provided between the first pixel row and the second pixel row; the light-shielding portion is configured as a strip shape extended along the first direction, and the orthographic projection of the light-shielding portion on the base substrate at least partially overlaps with an orthographic projection of the gap on the base substrate;
the first direction is parallel to the surface of the base substrate close to the light-emitting substrate, and the first direction intersects with the second direction.

In some embodiments of the present disclosure, the first sub-pixel, the second sub-pixel, and the third sub-pixel are provided with a same width in the second direction.

In some embodiments of the present disclosure, the light-shielding layer group comprises five light-shielding layers, including a first light-shielding layer, a second light-shielding layer, a third light-shielding layer, a fourth light-shielding layer and a fifth light-shielding layer sequentially arranged in a direction from the light-emitting substrate to the base substrate; the first light-shielding layer includes a plurality of first light-shielding portions, the second light-shielding layer includes a plurality of second light-shielding portions, the third light-shielding layer includes a plurality of third light-shielding portions, the fourth light-shielding layer includes a plurality of fourth light-shielding portions, and the fifth light-shielding layer includes a plurality of fifth light-shielding portions; an orthographic projection of a first light-shielding portion, an orthographic projection of a second light-shielding portion, an orthographic projections of a third light-shielding portion, an orthographic projection of a fourth light-shielding portion, and an orthographic projection of a fifth light-shielding portion on the base substrate overlap with each other.

In some embodiments of the present disclosure, a distance between a light-shielding layer farthest away from the light-emitting substrate and the sub-pixel is Z1; and

Z1=A/tan θ

where θ is a peep-proof viewing angle, and A is a width of the sub-pixel in the second direction.

In some embodiments of the present disclosure, a distance between the first light-shielding layer and the second light-shielding layer is Z2, and Z2=Z1×B(B+A); a distance between the second light-shielding layer and the third light-shielding layer is Z3, and Z3=(Z1−Z2)×B(B+A); a distance between the third light-shielding layer and the fourth light-shielding layer is Z4, and Z4=(Z1−Z2−Z3)×B(B+A); a distance between the fourth light-shielding layer and the fifth light-shielding layer is Z5, and Z5=(Z1−Z2−Z3−Z4)×B(B+A);
where B is a width of the first light-shielding portion in the second direction.

In some embodiments of the present disclosure, a distance between a light-shielding layer closest to the light-emitting substrate and the sub-pixel is Z6; and

Z6=(A+B) tan β,
where β is a critical angle; the light-shielding layer is not needed to be provided for shielding light with an angle greater than the critical angle; and B is a width of the first light-shielding portion in the second direction.

In some embodiments of the present disclosure, a thickness of the light-shielding layer is greater than or equal to 1 μm and less than or equal to 3 μm.

In some embodiments of the present disclosure, the display panel further includes:
an encapsulation layer group, provided on a side of the light-emitting substrate away from the base substrate, where at least a portion of a film layer of the encapsulation layer group is reused as the light-shielding layer group, or the encapsulation layer group is provided between the light-emitting substrate and the light-shielding layer group.

In some embodiments of the present disclosure, the light-shielding layer group further includes at least two spacing layers, and a spacing layer is provided between two adjacent light-shielding layers.

In some embodiments of the present disclosure, the light-shielding layer group comprises three light-shielding layers, including a first light-shielding layer, a second light-shielding layer and a third light-shielding layer sequentially arranged in a direction from the light-emitting substrate to the base substrate; the first light-shielding layer includes a plurality of first light-shielding portions, the second light-shielding layer includes a plurality of second light-shielding portions, and the third light-shielding layer includes a plurality of third light-shielding portions; an orthographic projection of a first light-shielding portion, an orthographic projection of a second light-shielding portion, and an orthographic projection of a third light-shielding portion on the base substrate overlap with each other; and the at least two spacing layers includes:
a first spacing layer, provided between the first light-shielding layer and the second light-shielding layer; and
a second spacing layer, provided between the second light-shielding layer and the third light-shielding layer, where a refractive index of the first spacing layer is less than or equal to a refractive index of the second spacing layer.

In some embodiments of the present disclosure, a plurality of second protrusion portions are provided on a surface of the second spacing layer away from the base substrate, and an orthographic projection of a second protrusion portion on the base substrate covers and is greater than an orthographic projection of a third light-shielding portion on the base substrate; and the first spacing layer includes a plurality of first protrusion portions, and a first protrusion portion covers a second light-shielding portion.

In some embodiments of the present disclosure, a plurality of first via holes are provided on the first spacing layer, and an orthographic projection of a first via hole on the base substrate at least partially overlaps with the orthographic projection of the sub-pixel on the base substrate.

In some embodiments of the present disclosure, a plurality of second via holes are provided on the second spacing layer, and an orthographic projection of a second via hole on the base substrate at least partially overlaps with the orthographic projection of the sub-pixel on the base substrate.

In some embodiments of the present disclosure, a plurality of second grooves are provided on the second spacing layer, and an orthographic projection of a second groove on the base substrate at least partially overlaps with the orthographic projection of the sub-pixel on the base substrate.

In some embodiments of the present disclosure, a plurality of first grooves are provided on the first spacing layer, and an orthographic projection of a first groove on the base substrate at least partially overlaps with the orthographic projection of the second groove on the base substrate.

In some embodiments of the present disclosure, the first groove is a blind hole, the second groove is a via hole, and the second groove is communicated with the first groove.

In some embodiments of the present disclosure, the display panel further includes:
a planarization layer, provided on a side of the light-shielding layer group away from the base substrate, where a refractive index of the planarization layer is greater than the refractive index of the second spacing layer.

In some embodiments of the present disclosure, the display panel further includes:
a touch layer group, provided on a side of the light-emitting substrate away from the base substrate, where the touch layer group includes touch wires, the touch wires are connected to form a grid shape, the light-shielding portion covers at least a portion of the touch wires, or a portion of a film layer of the touch layer group is reused as a portion of a film layer of the light-shielding layer group.

In some embodiments of the present disclosure, the touch layer group includes:
a barrier layer, provided on a side of the light-emitting substrate away from the base substrate;
a first touch layer, provided on a side of the barrier layer away from the base substrate, where the first touch layer includes first touch wires, and the first touch wires are connected to form a grid shape;
a touch insulating layer, provided on a side of the first touch layer away from the base substrate;
a second touch layer, provided on a side of the touch insulating layer away from the base substrate, where the second touch layer includes second touch wires, and the second touch wires are connected to form a grid shape; and
a protecting layer, provided on a side of the second touch layer away from the base substrate.

In some embodiments of the present disclosure, the barrier layer is reused as the second spacing layer, the second light-shielding portion covers at least a portion of the first touch wires, the touch insulating layer is reused as the first spacing layer, the first light-shielding portion covers at least a portion of the second touch wires, and the protecting layer is reused as the planarization layer.

In some embodiments of the present disclosure, the barrier layer is reused as the second spacing layer, the first touch layer is reused as the second light-shielding layer, the touch insulating layer is reused as the first spacing layer, and the second touch layer is reused as the first light-shielding layer.

In some embodiments of the present disclosure, the first touch layer is reused as the third light-shielding layer, the touch insulating layer is reused as the second spacing layer, the second touch layer is reused as the second light-shielding layer, and the protecting layer is reused as the first spacing layer.

In some embodiments of the present disclosure, the display panel further includes:
a color film layer, provided on a side of the light-shielding layer group away from the base substrate, where the color film layer includes a plurality of light-filtering portions, an overlapping portion is provided between two adjacent light-filtering portions, and an orthographic projection of the overlapping portion on the base substrate at least partially overlaps with the orthographic projection of the light-shielding portion on the base substrate.

In some embodiments of the present disclosure, the display panel further includes:
a color film layer, provided on a side of the light-shielding layer group away from the base substrate, where the color film layer includes a plurality of light-filtering portions and a light-blocking portion, the light-blocking portion is provided between two adjacent light-filtering portions, and an orthographic projection of the light-blocking portion on the base substrate at least partially overlaps with the orthographic projection of the light-shielding portion on the base substrate.

According to another aspect of the present disclosure, there is provided a display apparatus, including any one of the display panels described above.

It should be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a portion of the description, illustrate embodiments consistent with the disclosure and together with the description serve to explain the principles of the present disclosure. Obviously, the drawings in the following description are some embodiments of the present disclosure, and for those of ordinary skill in the art, other drawings can also be obtained from these drawings without creative efforts.

FIG. 1 is a schematic diagram showing that there is an inverted image of a vehicle-mounted display at night.

FIG. 2 is a schematic diagram showing that there is no inverted image of a vehicle-mounted display after being attached with an LCF at night.

FIG. 3 is a schematic structural diagram of an LCF film.

FIG. 4 is a schematic diagram of a curve of brightness change along with a viewing angle after an LCF is attached to a vehicle-mounted display.

FIG. 5 is a schematic structural diagram of a display panel according to some embodiments of the present disclosure.

FIG. 6 is a schematic structural diagram of a display panel according to some embodiments of the present disclosure.

FIG. 7 is a schematic structural diagram of a sub-pixel arrangement manner in a display panel according to some embodiments of the present disclosure.

FIG. 8 is a schematic structural diagram of a sub-pixel arrangement manner in a display panel according to some embodiments of the present disclosure.

FIG. 9 is a schematic diagram of a principle for calculating a distance between a first light-shielding layer and a sub-pixel.

FIG. 10 is a schematic diagram of a principle for calculating a distance between a first light-shielding layer and a second light-shielding layer.

FIG. 11 is a schematic diagram of a principle for calculating a distance between a second light-shielding layer and a third light-shielding layer.

FIG. 12 is a schematic diagram of a principle for calculating a distance between a third light-shielding layer and a fourth light-shielding layer.

FIG. 13 is a schematic diagram of a principle for calculating a distance between a fourth light-shielding layer and a fifth light-shielding layer.

FIG. 14 is a schematic diagram of a principle for providing a fourth light-shielding layer and a fifth light-shielding layer according to the present disclosure.

FIG. 15 is a schematic diagram of a specific structure of the light-shielding layer group in FIG. 5 and FIG. 6 according to a first example embodiment.

FIG. 16 is a schematic diagram of a light path principle of the light-shielding layer group in FIG. 15.

FIG. 17 is a schematic diagram of a specific structure of the light-shielding layer group in FIG. 5 and FIG. 6 according to a second example embodiment.

FIG. 18 is a schematic diagram of a light path principle of the light-shielding layer group in FIG. 17.

FIG. 19 is a schematic diagram of a specific structure of the light-shielding layer group in FIG. 5 and FIG. 6 according to a third example embodiment.

FIG. 20 is a schematic diagram of a specific structure of the light-shielding layer group in FIG. 5 and FIG. 6 according to a fourth example embodiment.

FIG. 21 is a schematic diagram of a specific structure of the light-shielding layer group in FIG. 5 and FIG. 6 according to a fifth example embodiment.

FIG. 22 is a schematic diagram of a specific structure of the light-shielding layer group in FIG. 5 and FIG. 6 according to a sixth example embodiment.

### DETAILED DESCRIPTION

Example embodiments will now be described more fully with reference to the accompanying drawings. Example embodiments, however, can be implemented in various forms and should not be construed as limited to the embodiments set forth here; by contrast, these embodiments are provided so that the present disclosure will be thorough and complete, and will fully convey the concept of example embodiments to those skilled in the art. The same reference numerals in the drawings denote the same or similar structures, and thus their detailed descriptions will be omitted. In addition, the drawings are merely schematic illustrations of the present disclosure, and are not necessarily drawn to scale.

Although relative terms such as “upper” and “lower” are used in the present description to describe the relative relationship of one component to another component shown in the drawings, these terms are used in the present description for convenience only, for example, according to the example direction described in the accompanying drawings. It will be appreciated that if the device shown in the drawings is flipped upside down, then the “upper” component will become the “under” component. When a certain structure is “on” the other structure, it may mean that a certain structure is integrally formed on the other structure, or that a certain structure is “directly” provided on the other structure, or that a certain structure is “indirectly” provided on the other structure through another structure.

The terms “a”, “an”, “the”, “said” and “at least one” are used to indicate the presence of one or more elements/components/etc.; the terms “comprising” and “including” are used to indicate an open inclusion and means that there may be additional elements/components/etc. in addition to the listed elements/components/etc.; the terms “first”, “second” and “third” etc. are only used as a marker, not a limitation on the number of its objects.

In the present disclosure, unless otherwise specified and limited, the term “connection” should be understood in abroad sense; for example, “connection” may refer to fixed connection, detachable connection, or be formed as a whole; and it may refer to be directly connected, or indirectly connected by using an intermediate medium. “And/or” is merely used to describe an association relationship of associated objects, and indicates that there may be three kind of relationships; for example, A and/or B may indicate three conditions that A exists alone, A and B exist simultaneously, and B exists alone. In addition, the character “/” in the present description generally indicates an “or” relationship between the associated objects before and after.

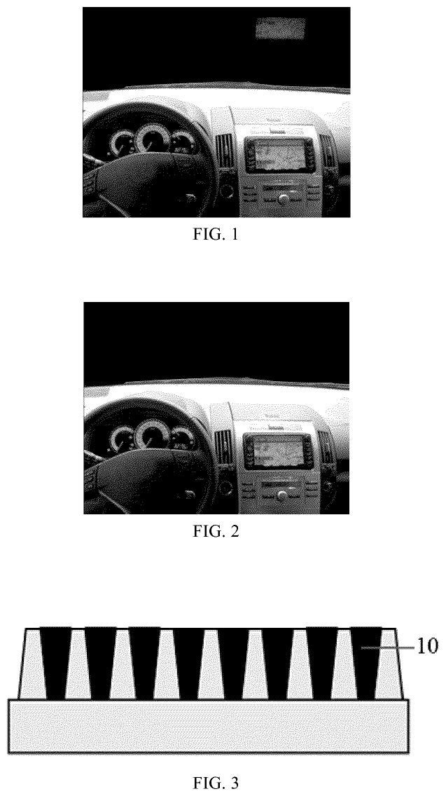

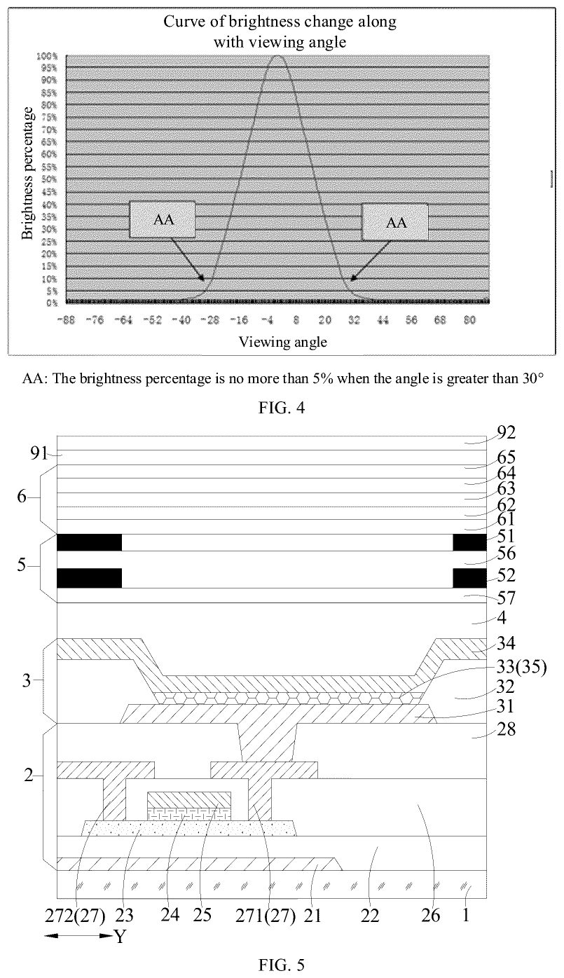

In the aspect of vehicle-mounted devices, referring to FIG. 1, since the display panel has no peep-proof function, there is a problem of inverted image for the vehicle-mounted display at night or in a severe weather environment, resulting in potential safety hazards. Referring to FIG. 2, an LCF (Light Control Film) film is attached to the vehicle-mounted display, which can avoid the inverted image. Referring to FIG. 3, the LCF film is an optical film that can be used to adjust the transmission of light, the structure of which is in the form of a shutter formed by the light-absorbing material 10. As shown in FIG. 4, due to the effect of the light-absorbing material 10, the image is visible when viewed in a vertical viewing angle; however, as the viewing angle increases, the amount of light transmitted through the LCF will be gradually reduced; when reaching a certain angle (e.g., 300) at which more than 95% of the light is blocked, the image will no longer be visible; therefore, it is avoided that the bright light with a large viewing angle from the vehicle-mounted display forms an inverted image through reflection image of the front windshield, which affects the sight of the driver, and results in a driving risk. However, after the LCF film is conventionally attached, the overall brightness of the vehicle-mounted display is greatly reduced and is reduced by about 25%. If the brightness requirement of the customer needs to be met, the requirement of the service life of the light-emitting device is higher, and the energy consumption is increased greatly.

Example embodiments of the present disclosure provide a display panel, and referring to FIG. 5 to FIG. 16, the display panel may include a base substrate 1, a light-emitting substrate 3, and a light-shielding layer group 5; the light-emitting substrate 3 is provided on a side of the base substrate 1, and the light-emitting substrate 3 may include a plurality of sub-pixels 35; the light-shielding layer group 5 is provided on a side of the light-emitting substrate 3 away from the base substrate 1, and the light-shielding layer group 5 may include at least two light-shielding layers 501; each light-shielding layer 501 may include a plurality of light-shielding portions 502, orthographic projections of the light-shielding portions 502 of each light-shielding layers 501 on the base substrate 1 at least partially overlaps with each other, and the orthographic projections of the light-shielding portions 502 on the base substrate 1 does not overlap with the orthographic projections of the sub-pixels 35 on the base substrate 1.

According to the display panel and the display apparatus of the present disclosure, the light-shielding portions 502 of the at least two light-shielding layers 501 may block light emitted from the sub-pixels 35 at a relatively larger angle, so as to prevent the light from being emitted to the eyes of the viewer from the side, thus achieving a peep-proof effect. Furthermore, the orthographic projections of the light-shielding portions 502 on the base substrate 1 do not overlap with the orthographic projections of the sub-pixels 35 on the base substrate 1, so that the light-shielding portions 502 do not affect the front light-emitting efficiency of the sub-pixels 35, thus not reducing the light-emitting brightness of the display panel, and not affecting the service life and energy consumption of the sub-pixels 35.

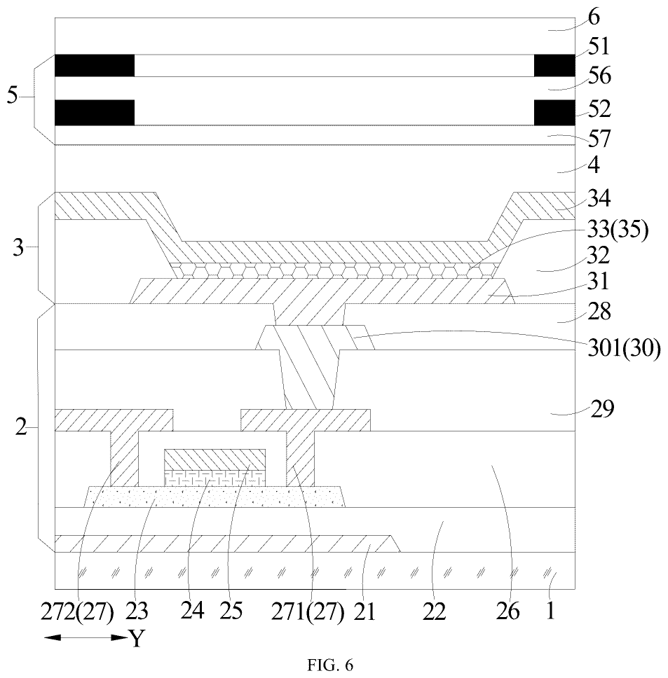

Referring to FIG. 5 and FIG. 6, the display panel may include a base substrate 1, a driving backplane 2, a light-emitting substrate 3, an encapsulation layer group 4, a light-shielding layer group 5, a touch layer group 6, a reflex reduction layer 91, and a cover plate, etc. The driving backplane 2 is provided on a side of the base substrate 1, and the light-emitting substrate 3 is provided on a side of the driving backplane 2 away from the base substrate 1. The encapsulation layer group 4 may be provided on a light-emitting side of the light-emitting substrate 3; that is, the encapsulation layer group 4 is provided on a side of the light-emitting substrate 3 away from the base substrate 1. The light-shielding layer group 5 is provided on a side of the encapsulation layer group 4 away from the base substrate 1.

The driving backplane 2 may include a plurality of driving circuits arranged in an array. The light-emitting substrate 3 may include a plurality of light-emitting devices arranged in an array, and the driving circuit may drive the light-emitting device to emit light.

In the example embodiment, the material of the base substrate 1 may include an inorganic material; for example, the inorganic material may be glass, quartz, metal, or the like. The material of the base substrate 1 may further include an organic material; for example, the organic material may be a resin material such as polyimide, polycarbonate, polyacrylate, polyetherimide, polyethersulfone, polyethylene terephthalate, and polyethylene naphthalate, etc. The base substrate 1 may be formed by a plurality of material layers; for example, the base substrate 1 may include a plurality of base layers, and the material of the base layer may be any of the foregoing materials. In some embodiments, the base substrate 1 may also be provided as a single layer, which may be any one of the materials described above.

A shielding layer 21 may be further provided on a side of the base substrate 1. Light incident into the active layer 23 from the base substrate 1 may generate photo-generative carriers in the active layer 23, thus greatly affecting the characteristics of the thin film transistor, and finally affecting the display quality of the display apparatus. The light emitted from the base substrate 1 may be shielded by the shielding layer 21, thus avoiding affecting the characteristics of the thin film transistor and avoiding affecting the display image quality of the display apparatus.

The buffer layer 22 may also be formed on the side of the shielding layer 21 away from the base substrate 1. The buffer layer 22 functions to block water vapor and impurity ions in the base substrate 1 (in particular, an organic material), and functions to increase hydrogen ions for the subsequently formed active layer 23. The material of the buffer layer 22 is an insulating material, which can insulate and isolate the shielding layer 21 from the active layer 23.

The active layer 23 is provided on a side of the buffer layer 22 away from the base substrate 1. The active layer 23 may include a channel portion and conductor portions provided at two ends of the channel portion. A gate insulating layer 24 is provided on a side of the active layer 23 away from the base substrate 1. A gate 25 is provided on a side of the gate insulating layer 24, and an interlayer dielectric layer 26 is provided on a side of the gate 25 away from the substrate 1. A via hole is provided on the interlayer dielectric layer 26, and is communicated with the conductor portion. A first source-drain layer 27 is provided on a side of the interlayer dielectric layer 26 away from the base substrate 1; the first source-drain layer 27 may include a source 271 and a drain 272; and the source 271 and the drain 272 are respectively connected to the two conductor portions through two via holes. A passivation layer 28 is provided on a side of the source 271 and the drain 272 away from the base substrate 1; a via hole is provided on the passivation layer 28, and is connected to the source 271. The active layer 23, the gate 25, the source 271, and the drain 272 form a thin film transistor.

Referring to FIG. 6, in some embodiments of the present disclosure, a source-drain insulating layer 29 is provided on a side of the first source-drain layer 27 away from the base substrate 1, and a via hole is also provided on the source-drain insulating layer 29. A second source-drain layer 30 is provided on a side of the source-drain insulating layer 29 away from the base substrate 1; the second source-drain layer 30 may include a connecting structure 301, and the connecting structure 301 is connected to the source 271 through a via hole on the interlayer dielectric layer 26. In some embodiments, a third source-drain layer, a fourth source-drain layer, and so on may also be provided as needed.

It should be noted that the thin film transistor described in the present description is a top gate type thin film transistor, and in some embodiments of the present disclosure, the thin film transistor may also be a bottom gate type or a double gate type, the specific structure of which will not be repeated here. Moreover, the functions of “source 271” and “drain 272” are sometimes interchanged with each other in the cases that thin film transistors with opposite polarities are used or the current direction during circuit operation changes. Thus, in the present description, “source 271” and “drain 272” may be interchanged with each other.

Continuing to refer to FIG. 5 and FIG. 6, the light-emitting substrate 3 is provided on a side of the passivation layer 28 away from the base substrate 1. The light-emitting substrate 3 may include a first electrode 31, a pixel definition layer 32, a light-emitting layer group 33, and a second electrode 34.

In some embodiments, a first electrode 31 is provided on a side of the passivation layer 28 away from the base substrate 1, the first electrode 31 is connected to a source 271 of the driving backplane 2 through a via hole, and the first electrode 31 may be an anode (a pixel electrode).

A pixel definition layer 32 is provided on a side of the first electrode 31 away from the base substrate 1, an opening portion is provided on the pixel definition layer 32, and the opening portion exposes at least a portion of the first electrode 31. A light-emitting layer group 33 is provided within the opening portion, and the light-emitting layer group 33 is in contact connection with the first electrode 31. A second electrode 34 is provided on a side of the light-emitting layer group 33 away from the base substrate 1, the second electrode 34 may be a cathode (a common electrode), and the second electrode 34 is connected to the ground line VSS. The light-emitting layer group 33 within an opening portion forms a sub-pixel 35. Therefore, the light-emitting layer group 33 within an opening portion is a sub-pixel 35, so that the orthographic projection of the sub-pixel 35 on the base substrate 1 is the orthographic projection of the light-emitting layer group 33 on the base substrate 1. The light-emitting substrate 3 may include a plurality of sub-pixels 35.

The light-emitting layer group 33 may include a hole injection layer, a hole transport layer, a light-emitting layer, an electron transport layer and an electron injection layer which are sequentially stacked. The hole injection layer is in contact connection with the first electrode 31, and the electron injection layer is in contact connection with the second electrode 34. In some embodiments of the present disclosure, the light-emitting layer group 33 may only include a hole transport layer, a light-emitting layer, and an electron transport layer. The light-emitting layer group 33 may also be of other structures, and the specific structure may be provided as needed.

An encapsulation layer group 4 is provided on a side of the second electrode 34 away from the base substrate 1. The encapsulation layer group 4 may be provided as a plurality of layers. The encapsulation layer group 4 may include an organic layer and an inorganic layer. In some embodiments, the encapsulation layer group 4 may include a first inorganic layer, an organic layer provided on a side of the first inorganic layer away from the base substrate 1, and a second inorganic layer provided on a side of the organic layer away from the base substrate 1. Materials of the first inorganic layer, the organic layer, and the second inorganic layer are not described here again. Certainly, the encapsulation layer group 4 may further include more layers or fewer layers.

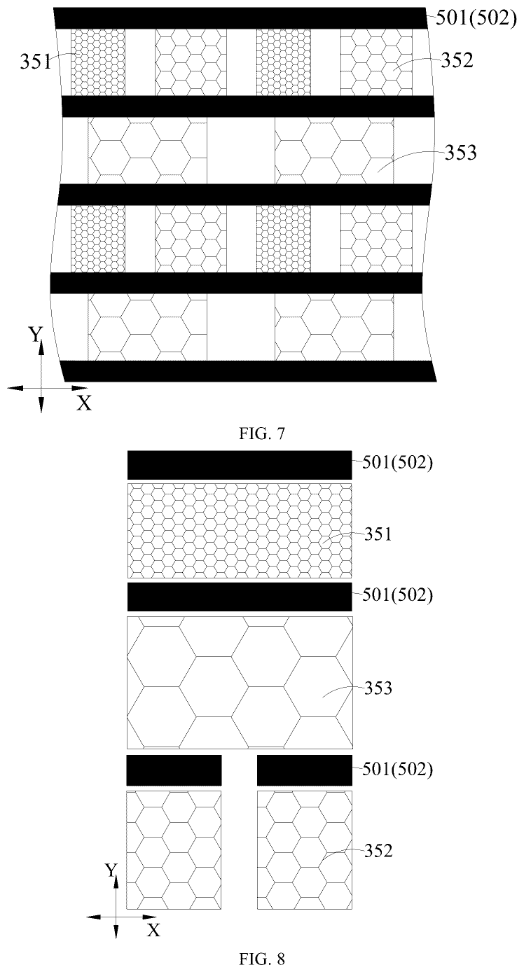

Referring to FIG. 5 and FIG. 6, a light-shielding layer group 5 is provided on a side of the encapsulation layer group 4 away from the base substrate 1. As shown in FIG. 7 and FIG. 8, the light-shielding portion 502 is located on at least one side of the sub-pixel 35 along the second direction Y, and the second direction Y is a peep-proof direction. That is, peep-proof is realized in the second direction. For example, when the user on the passenger seat watches the video, the person on the driver seat cannot see the video. Alternatively, the second direction may be a direction from the driving platform to the windshield. The light from the display panel will not be emitted to the windshield, and may not be imaged on the windshield.

In some embodiments, referring to FIG. 7 which shows the schematic structural diagram of the arrangement manner of the sub-pixels 35 according to some embodiments, the plurality of sub-pixels 35 include first sub-pixels 351, second sub-pixels 352, and third sub-pixels 353 with different colors. A plurality of first sub-pixels 351 and a plurality of second sub-pixels 352 are alternately arranged along the first direction X to form a first pixel row; that is, a second sub-pixel 352 is provided between two adjacent first sub-pixels 351, and a first sub-pixel 351 is provided between two adjacent second sub-pixels 352. That is, two kinds of sub-pixels 35 (e.g., a first sub-pixel 351 and a second sub-pixel 352) are provided within the first pixel row. A plurality of third sub-pixels 353 are arranged along the first direction X to form a second pixel row; that is, one kind of sub-pixel 35 (e.g., a third sub-pixel 353) is provided within the second pixel row.

A plurality of first pixel rows and a plurality of second pixel rows are alternately arranged in the second direction Y; that is, a second pixel row is provided between two adjacent first pixel rows, and a first pixel rows is provided between two adjacent second pixel rows. A gap is provided between the first pixel row and the second pixel row.

The light-shielding portion 502 may be configured as a strip shape extending along the first direction X. An orthographic projection of the light-shielding portion 502 on the base substrate 1 at least partially overlaps with an orthographic projection of the gap on the base substrate 1. In some embodiments, the orthographic projection of the light-shielding portion 502 on the base substrate 1 may coincide with the orthographic projection of the gap on the base substrate 1. Alternatively, a portion of the orthographic projection of the light-shielding portion 502 on the base substrate 1 may overlaps with a portion of the orthographic projection of the gap on the base substrate 1. Alternatively, the orthographic projection of the light-shielding portion 502 on the base substrate 1 may be located within the orthographic projection of the gap on the base substrate 1, so as to prevent the light-shielding portion 502 from blocking the light emitted from each sub-pixel 35, thus avoiding reducing the light-emitting efficiency of the display panel.

Moreover, the light-shielding portions 502 are provided on both sides of each sub-pixel 35 along the second direction Y When the display panel is used in the vehicle-mounted display apparatus, both sides of the light-shielding portion 502 may be provided close to the windshield, so that the light-shielding portion 502 can shield the light emitted by each sub-pixel from being emitted to the windshield, and there is no inverted image of the display apparatus formed on the windshield, thus the sight of the driver is not affected, and potential safety hazards are avoided. Moreover, there is no person viewing from the side of the vehicle-mounted display apparatus away from the windshield, thus the shielding portion 502 does not affect the viewer.

It should be noted that, in the present disclosure, the first direction X and the second direction Y are parallel to a surface of the base substrate 1 close to the light-emitting substrate 3, and the first direction X intersects with the second direction Y For example, the first direction X is perpendicular to the second direction Y Moreover, the “parallel” and “perpendicular” mentioned in the present disclosure may not be completely parallel and perpendicular, but may have a certain error. For example, when the included angle between two directions is greater than or equal to 0° and less than or equal to 5°, the two directions are considered to be parallel to each other; when the included angle between the two directions is greater than or equal to 85° and less than or equal to 95°, the two directions are considered to be perpendicular to each other.

The so-called “coinciding” is not completely coinciding. Due to reasons such as process error, when the area of the overlapping portion between the orthographic projection of the light-shielding portion 502 on the base substrate 1 and the orthographic projection of the gap on the base substrate 1 is 95% or more of the area of the orthographic projection of the gap on the base substrate 1, it may be considered that the orthographic projection of the light-shielding portion 502 on the base substrate 1 coincides with the orthographic projection of the gap on the base substrate 1. Alternatively, when the distance between the edge of the orthographic projection of the light-shielding portion 502 on the base substrate 1 and the edge of the orthographic projection of the gap on the base substrate 1 is less than or equal to 4 m (micron), it may also be considered that the orthographic projection of the light-shielding portion 502 on the base substrate 1 coincides with the orthographic projection of the gap on the base substrate 1.

In addition, the arrangement of the sub-pixels is not limited to the above description. As shown in FIG. 8, one first sub-pixel 351 and one third sub-pixel 353 are arranged in the second direction Y to form a row, and the two second sub-pixels 352 are provided on a side of the third sub-pixel 353 away from the first sub-pixel 351. One first sub-pixel 351, one third sub-pixel 353, and two second sub-pixels 352 form a pixel. The plurality of pixels may be arranged according to requirements, and details are not described here again.

The light-shielding portion 502 is provided on a side of each sub-pixel along the second direction Y When the display panel is used for the vehicle-mounted display apparatus, the side provided with the light-shielding portion 502 is close to the windshield, so that the light-shielding portion 502 can shield the light emitted by each sub-pixel from being emitted to the windshield, and there may be no inverted image of the display apparatus formed on the windshield, thus the sight of the driver may not be affected, and potential safety hazards may be avoided.

In addition, the light-shielding portion 502 may also be provided corresponding to each sub-pixel; that is, a light-shielding portion 502 is provided on a side of a sub-pixel.

When the display panel is used for the vehicle-mounted display apparatus, the angles for the driver and the user on the passenger seat to view the display panel are generally inclined. Therefore, there is no light-shielding portions 502 provided on either side of each sub-pixel 35 along the first direction X, so that the driver and the user on the passenger seat can view the display panel on both sides along the first direction X without affecting their viewing.

In some embodiments of the present disclosure, the light-shielding portion 502 may be provided on the periphery of each sub-pixel, so that the display panel has a peep-proof function in a range of 360°.

In some embodiments, the first sub-pixel 351 may be a red sub-pixel, the second sub-pixel 352 may be a green sub-pixel, and the third sub-pixel 353 may be a blue sub-pixel. In some embodiments of the present disclosure, the first sub-pixel 351 may be a green sub-pixel or a blue sub-pixel, the second sub-pixel 352 may be a red sub-pixel or a blue sub-pixel, and the third sub-pixel 353 may be a red sub-pixel or a green sub-pixel.

Moreover, referring to FIG. 7, the first sub-pixel 351, the second sub-pixel 352, and the third sub-pixel 353 have the same width in the second direction Y In this way, when the user views the display panel in an inclined angle, the width of each sub-pixel 35 shielded by the light-shielding portion 502 is the same, and the width of each sub-pixel 35 that is not shielded by the light-shielding portion 502 is also the same. Therefore, the ratio of the area of the visible first sub-pixel 351, the second sub-pixel 352, and the third sub-pixel 353 is not changed, and thus, there may be no color shift when it is viewed in an inclined angle.

The distance between two adjacent light-shielding layers 501 increases as the distance between the light-shielding layer 501 close to or far away from the base substrate 1 and the base substrate 1 increases.

For example, in order to achieve a viewing angle of 30°, 95% of brightness is blocked, and the light-shielding layer group 5 may include five light-shielding layers 501, which includes a first light-shielding layer 51, a second light-shielding layer 52, a third light-shielding layer 53, a fourth light-shielding layer 54, and a fifth light-shielding layer 55 sequentially in a direction from the light-emitting substrate 3 to the base substrate 1. That is, the fifth light-shielding 55 is closer to the base substrate 1 than the first light-shielding layer 51. The materials of the first light-shielding layer 51, the second light-shielding layer 52, the third light-shielding layer 53, the fourth light-shielding layer 54, and the fifth light-shielding layer 55 may be organic materials; in some embodiments, the material may be a black resin, which may be formed through a photolithography process. The thickness of each light-shielding layer 501 is greater than or equal to 1 μm and less than or equal to 3 μm. For example, the thickness of the light-shielding layer 501 is 1.2 μm, 1.5 μm, 1.75 μm, 2 μm, 2.2 μm, 2.45 μm, 2.7 μm, 2.9 μm, etc.

The first light-shielding layer 51 may include a plurality of first light-shielding portions 511, the second light-shielding layer 52 may include a plurality of second light-shielding portions 521, the third light-shielding layer 53 may include a plurality of third light-shielding portions 531, the fourth light-shielding layer 54 may include a plurality of fourth light-shielding portions 541, and the fifth light-shielding layer 55 may include a plurality of fifth light-shielding portions 551. The orthographic projections of the first light-shielding portion 511, of the second light-shielding portion 521, of the third light-shielding portion 531, of the fourth light-shielding portion 541, and of the fifth light-shielding portion 551 on the base substrate 1 may coincide with each other.

The so-called “coinciding” is not completely coinciding. Due to reasons such as process error, when the area of the overlapping portion of the orthographic projections of the first light-shielding portion 511, of the second light-shielding portion 521, of the third light-shielding portion 531, of the fourth light-shielding portion 541, and of the fifth light-shielding portion 551 on the base substrate 1 is more than 95% of the area of the orthographic projection of the first light-shielding portion 511 on the base substrate 1, it may be considered that the orthographic projections of the first light-shielding portion 511, of the second light-shielding portion 521, of the third light-shielding portion 531, of the fourth light-shielding portion 541, and of the fifth light-shielding portion 551 on the base substrate 1 coincide with each other.

In some embodiments, the first light-shielding portion 511, the second light-shielding portion 521, the third light-shielding portion 531, the fourth light-shielding portion 541, and the fifth light-shielding portion 551 may also be configured to gradually increase or gradually decrease in structure according to requirements.

The light-shielding layer group 5 may further include five spacing layers, which includes a first spacing layer 56, a second spacing layer 57, a third spacing layer 58, a fourth spacing layer 59, and a fifth spacing layer 60 sequentially in a direction from the light-emitting substrate 3 to the base substrate 1. That is, the fifth spacing layer 60 is closer to the base substrate 1 than the first spacing layer 56. Materials of the first spacing layer 56, the second spacing layer 57, the third spacing layer 58, the fourth spacing layer 59, and the fifth spacing layer 60 may be transparent organic materials, for example, it may be an acrylic resin and an epoxy resin; the light transmittance of this transparent organic material is relatively higher, for example, the light transmittance is greater than or equal to 92%; therefore, the influence on the light transmittance of the display panel is not obvious, the overall brightness of the display panel is not reduced, there is no higher requirement on the service life of the light-emitting layer group 33, and the energy consumption of the display panel is not increased. The five spacing layers may be formed through an inkjet printing process.

The fifth spacing layer 60 is provided on a side of the encapsulation layer group 4 away from the base substrate 1, and the fifth light-shielding layer 55 is provided on a side of the fifth spacing layer 60 away from the base substrate 1. The fourth spacing layer 59 is provided on a side of the fifth light-shielding layer 55 away from the base substrate 1, and the fourth light-shielding layer 54 is provided on a side of the fourth spacing layer 59 away from the base substrate 1. The third spacing layer 58 is provided on a side of fourth light-shielding layer 54 away from the base substrate 1, and the third light-shielding layer 53 is provided on a side of the third spacing layer 58 away from the base substrate 1. The second spacing layer 57 is provided on a side of the third light-shielding layer 53 away from the base substrate 1, and the second light-shielding layer 52 is provided on a side of the second spacing layer 57 away from the base substrate 1. The first spacing layer 56 is provided on a side of the second light-shielding layer 52 away from the base substrate 1, and the first light-shielding layer 51 is provided on a side of the first spacing layer 56 away from the base substrate 1.

The distance between each light-shielding layer 501 and the sub-pixel 35 is described in detail below.

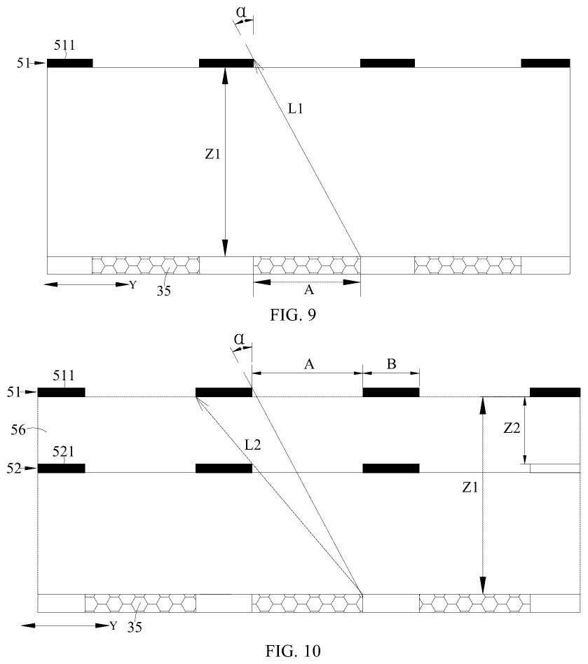

Referring to FIG. 9, the light L1 is a peep-proof critical light. The critical light is just blocked by the light-shielding layer 501 farthest away from the light-emitting substrate 3. The light-shielding layer 501 farthest away from the light-emitting substrate 3 may be the first light-shielding layer 51. The distance between the light-shielding layer 501 farthest away from the light-emitting substrate 3 and the sub-pixel 35 is Z1, that is, the distance between the first light-shielding layer 51 and the sub-pixel 35 is Z1, and

Z1=A/tan θ,
where, θ is a peep-proof viewing angle, the value of which may be 30°, in some embodiments, it may be set according to requirements; A is a width of the sub-pixel 35 in the second direction Y.

Referring to FIG. 10, the light L2 in the drawing is the peep-proof critical light of the first light-shielding layer 51 and the second light-shielding layer 52. This critical light is the light shielded both by the first light-shielding layer 51 and by the second light-shielding layer 52. The distance between the first light-shielding layer 51 and the second light-shielding layer 52 is Z2, and

$$Z 2 = Z 1 \times B / ( B + A ) ,$$

where, B is a width of the first light-shielding portion 511 in the second direction Y.

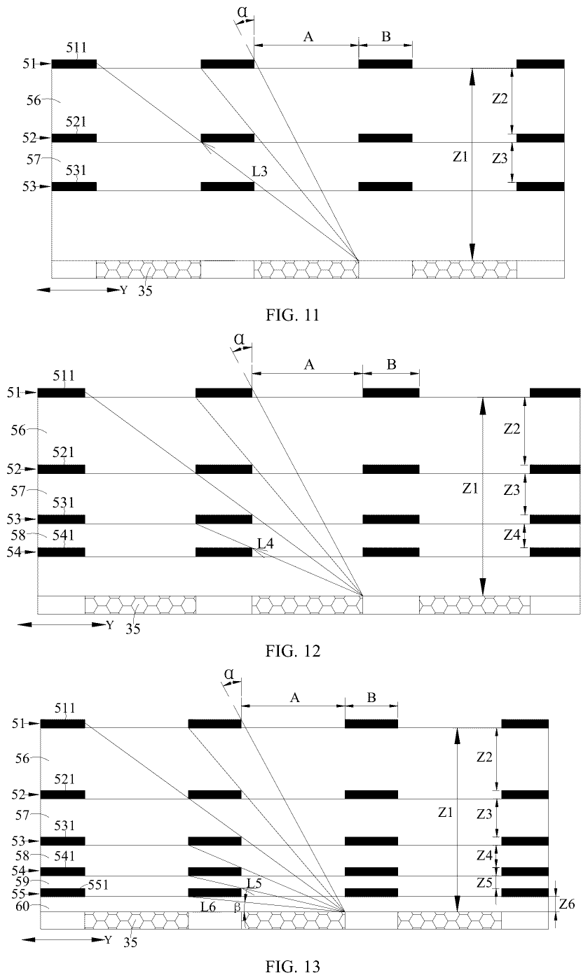

Referring to FIG. 11, the light L3 in the drawing is the peep-proof critical light of the second light-shielding layer 52 and the third light-shielding layer 53. This critical light is the light shielded both by the second light-shielding layer 52 and by the third light-shielding layer 53. The distance between the second light-shielding layer 52 and the third light-shielding layer 53 is Z3, and Z3=(Z1−Z2)×B(B+A).

Referring to FIG. 12, the light L4 in the drawing is the peep-proof critical light of the third light-shielding layer 53 and the fourth light-shielding layer 54. This critical light is the light shielded both by the third light-shielding layer 53 and by the fourth light-shielding layer 54. The distance between the third light-shielding layer 53 and the fourth light-shielding layer 54 is Z4, and Z4=(Z1-Z2-Z3)×B(B+A).

Referring to FIG. 13, the light L5 in the drawing is the peep-proof critical light of the fourth light-shielding layer 54 and the fifth light-shielding layer 55. This critical light is the light shielded both by the fourth light-shielding layer 54 and by the fifth light-shielding layer 55. The distance between the fourth light-shielding layer 54 and the fifth light-shielding layer 55 is Z5, and Z5=(Z1-Z2-Z3-Z4)×B(B+A).

Furthermore, since the front light-emitting efficiency of the sub-pixel is the highest, the light-emitting efficiency of the sub-pixel per se may be reduced as the viewing angle increases, and the brightness may also be reduced. For example, when the viewing angle is greater than or equal to 70°, the brightness of the sub-pixel is reduced to less than 20%. In addition to shielding of the touch layer group 6, the color film layer 8, the adjacent light-shielding portion 502, it results in that the maximum light that can be emitted is less than 10% when the viewing angle is greater than or equal to 70°. In the case that the viewing angle is greater than or equal to 70°, the brightness of the sub-pixel of the display panel does not exceed 5% (10%×20%=2%<5%). Therefore, In the case that the viewing angle is greater than or equal to 70°, there is no need to provide the light-shielding layer 501 for light shielding.

As shown in FIG. 13, the light L6 in the drawing is a critical light that does not need to be light shielded by providing the light-shielding layer 501. The light with an angle that is greater than the angle of the critical light does not need to be shielded by providing a shielding layer, and does not form a peeping light. The light-shielding layer 501 closest to the light-emitting substrate 3 may be the fifth light-shielding layer 55. The distance between the light-shielding layer 501 farthest away from the light-emitting substrate 3 and the sub-pixel 35 is Z6; that is, the distance between the fifth light-shielding layer 55 and the sub-pixel 35 is Z6, and

$$Z 6 = ( A + B ) tan β ,$$

where β is the critical angle, the light with an angel greater than the critical angle does not need to be shielded by providing the light-shielding layer 501, and the value of R may be 70°. In some embodiments, the value of 3 may be set according to requirements.

For example, in the case that A=55 μm and B=20 μm, it can be obtained by calculation that Z1=95 μm, Z2=25 μm, Z3=19 μm, Z4=16 μm, and Z5=10 μm.

Through the first light-shielding layer 51, the second light-shielding layer 52, the third light-shielding layer 53, the fourth light-shielding layer 54 and the fifth light-shielding layer 55, all light with an angle that is greater than or equal to the peep-proof angle θ and less than or equal to the critical angle R can be completely shielded, thus achieving a peep-proof effect.

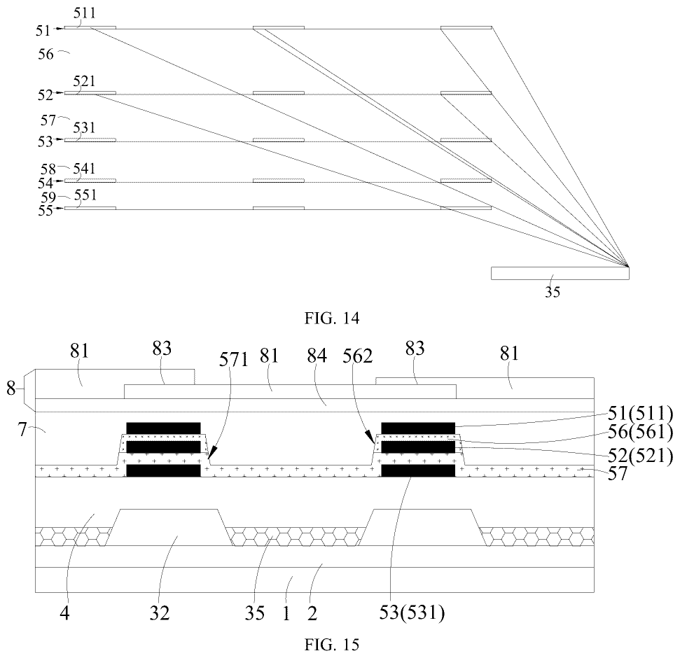

In addition, in some embodiments of the present disclosure, as shown in FIG. 14, since the viewing angles of light emitted to the fourth light-shielding layer 54 and the fifth light-shielding layer 55 are relatively larger, the light-emitting conditions of two adjacent columns of light-shielding portions 502 may also be considered when the fourth light-shielding layer 54 and the fifth light-shielding layer 55 are provided. For example, the distance between the fourth light-shielding portion 541 and the third light-shielding portion 531 may be appropriately increased, so that the light emitted from the gap between the fourth light-shielding portion 541 and the third light-shielding portion 531 may be shielded by the adjacent first light-shielding portion 511 to achieve the peep-proof effect. The distance between the fifth light-shielding portion 551 and the fourth light-shielding portion 541 may be appropriately increased, so that the light emitted from the gap between the fifth light-shielding portion 551 and the fourth light-shielding portion 541 may be shielded by the adjacent second light-shielding portion 521 to achieve the peep-proof effect. The arrangement of the fourth light-shielding portion 541 and the fifth light-shielding layer 55 may be obtained by calculation through drawing software.

In addition, in some embodiments of the present disclosure, for the specific structure of the light-shielding layer 501 with five layers described above, two layers, three layers, four layers, six layers, or more layers of the light-shielding layer 501 may be provided. Moreover, in the case that only two layers of the light-shielding layer 501 are provided, the first light-shielding layer and the second light-shielding layer may be provided. Since the front light-emitting efficiency of the sub-pixel is relatively higher, it can achieve a better light-shielding effect through providing the first light-shielding layer and the second light-shielding layer. In the case that only three layers of the light-shielding layer are provided, the first light-shielding layer, the second light-shielding layer, and the third light-shielding layer may be provided. Since the front light-emitting efficiency of the sub-pixel is relatively higher, it can achieve a better light-shielding effect through providing the first light-shielding layer, the second light-shielding layer and the third light-shielding layer.

It should be noted that, in the above calculation, the thicknesses of the first light-shielding layer 51, the second light-shielding layer 52, the third light-shielding layer 53, the fourth light-shielding layer 54 and the fifth light-shielding layer 55 are relatively thinner, which may be ignored.

In some embodiments of the present disclosure, a portion of the film layers of the encapsulation layer group 4 may be reused as the light-shielding layer group 5. For example, the organic layer may be reused as a light-shielding layer 501, the second inorganic layer is reused as a spacing layer, and another light-shielding layer 501 and another spacing layer are provided on a side of the second inorganic layer away from the base substrate. In some embodiments, the encapsulation layer group 4 may also be provided as a structure with more layers, and each film layer of the encapsulation layer group 4 is reused as the light-shielding layer 501 or the spacing layer of the light-shielding layer group 5. In this way, the number of film layers can be reduced, so that the display panel is lighter and thinner, and can be suitable for the bending display apparatus.

Referring to FIG. 15, in some embodiments of the present disclosure, three layers of light-shielding layer 501 are provided, which include a first light-shielding layer 51, a second light-shielding layer 52, and a third light-shielding layer 53 sequentially in a direction from the light-emitting substrate 3 to the base substrate 1; that is, the third light-shielding layer 53 is closer to the base substrate 1 than the first light-shielding layer 51. Materials of the first light-shielding layer 51, the second light-shielding layer 52, and the third light-shielding layer 53, may be organic materials; in some embodiments, the material may be a black resin, which may be formed through a photolithography process.

In this case, the spacing layer may be provided as two layers, respectively a first spacing layer 56 and a second spacing layer 57. The first spacing layer 56 is provided between the first light-shielding layer 51 and the second light-shielding layer 52. The second spacing layer 57 is provided between the second light-shielding layer 52 and the third light-shielding layer 53. That is, the light-shielding layer group 5 includes a first light-shielding layer 51, a first spacing layer 56, a second light-shielding layer 52, a second spacing layer 57, and a third light-shielding layer 53 sequentially from a side away from the base substrate 1.

The refractive index of the first spacing layer 56 is less than or equal to the refractive index of the second spacing layer 57.

The display panel may further include a planarization layer provided on a side of the light-shielding layer group away from the base substrate, and the refractive index of the planarization layer is greater than the refractive index of the second spacing layer.

The first light-shielding layer 51 may include a plurality of first light-shielding portions 511, the second light-shielding layer 52 may include a plurality of second light-shielding portions 521, and the third light-shielding layer 53 may include a plurality of third light-shielding portions 531. Orthographic projections of the first light-shielding portions 511, of the second light-shielding portions 521, and of the third light-shielding portions 531 on the base substrate 1 may coincide with each other.

The so-called “coinciding” is not completely coinciding. Due to reasons such as process error, when the area of the overlapping portion of the orthographic projections of the first light-shielding portion 511, of the second light-shielding portion 521, and of the third light-shielding portion 531 on the base substrate 1 is more than 95% of the area of the orthographic projection of the first light-shielding portion 511 on the base substrate 1, it may be considered that the orthographic projections of the first light-shielding portion 511, of the second light-shielding portion 521, and of the third light-shielding portion 531on the base substrate 1 coincide with each other.

In some embodiments, the first light-shielding portion 511, the second light-shielding portion 521, and the third light-shielding portion 531 may also be configured to gradually increase or gradually decrease in structure according to requirements.

In addition, the second spacing layer 57 covers the light-shielding portion of the first light-shielding layer 51 to form a second protrusion portion 571; that is, a second protrusion portion 571 is provided on a side of the second spacing layer 57 away from the base substrate 1, and an orthographic projection of the second protrusion portion 571 on the base substrate 1 covers and is greater than an orthographic projection of the third light-shielding portion 531 on the base substrate 1. The first spacing layer 56 may include a plurality of first protrusion portions 561, and a first protrusion portion 561 covers a light-shielding portion 521 of the second light-shielding layer, so that an orthographic projection of the first protrusion portion 561 on the base substrate 1 covers and is greater than an orthographic projection of the second light-shielding portion 521 on the base substrate 1.

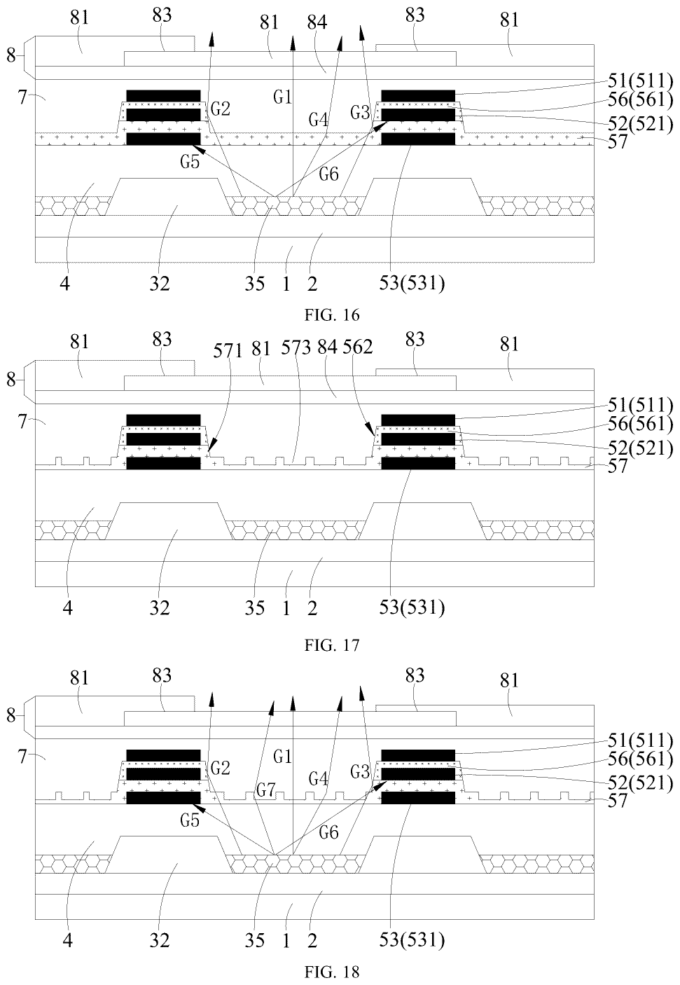

As shown in FIG. 16, the light G1 emitted from the front of the sub-pixel 35 is directly emitted. The lights G2 and G3 emitted from the sub-pixel 35 with a relatively larger viewing angle are emitted to the side wall of the first protruding portion 561 and the side wall of the second protruding portion 571. The side wall of the first protruding portion 561 and the side wall of the second protruding portion 571 reflect the light, so that the light is emitted from the front of the display panel, thus improving the light-emitting efficiency of the display panel, and avoiding reduction of the light-emitting efficiency of the display panel due to the fact that the light with a relatively larger viewing angle is absorbed by the first light-shielding portion 511 and the second light-shielding portion 521. Moreover, in the interface between the second spacing layer and the planarization layer, since the refractive index of the planarization layer is greater than the refractive index of the second spacing layer, the light G4 emitted from the second spacing layer to the planarization layer is emitted from the optically thinner medium to the optically denser medium, so that the exit angle of the light is smaller than the incidence angle of the light, and the light is converged to the center, thus improving the front light-emitting efficiency of the display panel.

As shown in FIG. 16, the lights G5 and G6 emitted from the sub-pixel 35 with a larger viewing angle may be emitted to the first light-shielding portion 511 and the second light-shielding portion 521, and may be directly absorbed by the first light-shielding portion 511 and the second light-shielding portion 521, thus avoiding effect on driving safety at night due to the fact that the light at a large viewing angle enters the human eyes or is reflected to the adjacent glass to cause reflection, and achieving the peep-proof effect.

Moreover, a plurality of first via holes 562 are provided on the first spacing layer 56, and an orthographic projection of a first via hole 562 on the base substrate 1 at least partially overlaps with an orthographic projection of the sub-pixel 35 on the base substrate 1. For example, it may be that the orthographic projection of the first via hole 562 on the base substrate 1 covers and is greater than the orthographic projection of the sub-pixel 35 on the base substrate 1, or a portion of the orthographic projection of the first via hole 562 on the base substrate 1 overlaps with a portion of the orthographic projection of the sub-pixel 35 on the base substrate 1, or the orthographic projection of the sub-pixel 35 on the base substrate 1 covers and is greater than the orthographic projection of the first via hole 562 on the base substrate 1. In this way, at least a portion of the front light-emitting side of the sub-pixel 35 is not covered by the first spacing layer 56, so as to avoiding effect on the front light-emitting efficiency of the display panel due to the fact that the light emitted from the front of the sub-pixel 35 is reflected at the interface between the second spacing layer 57 and the first spacing layer 56. In the case that the material and the refractive index of the second spacing layer 57 are the same as the material and the refractive index of the first spacing layer 56, the first via hole 562 may not be provided on the first spacing layer 56.

Furthermore, referring to FIG. 17, a plurality of second grooves 573 may be provided on the second spacing layer 57, and an orthographic projection of a second groove 573 on the base substrate 1 at least partially overlaps with an orthographic projection of the sub-pixel 35 on the base substrate 1. In some embodiments, the orthographic projection of the sub-pixel 35 on the base substrate 1 covers orthographic projections of a plurality of second grooves 573 on the base substrate 1.

As shown in FIG. 18, in this way, the inclined light G7 emitted from the sub-pixel 35 is emitted to the side wall of the second groove 573, and the side wall of the second groove 573 reflects the light, so that the light is emitted from the front of the display panel as much as possible, and the light-emitting efficiency of the display panel is improved. Moreover, the bonding force between the second spacing layer 57 and the subsequently formed planarization layer 7 is improved through the second groove 573, thus avoiding the peeling between the planarization layer 7 and the second spacing layer 57, and improving the reliability of the product.

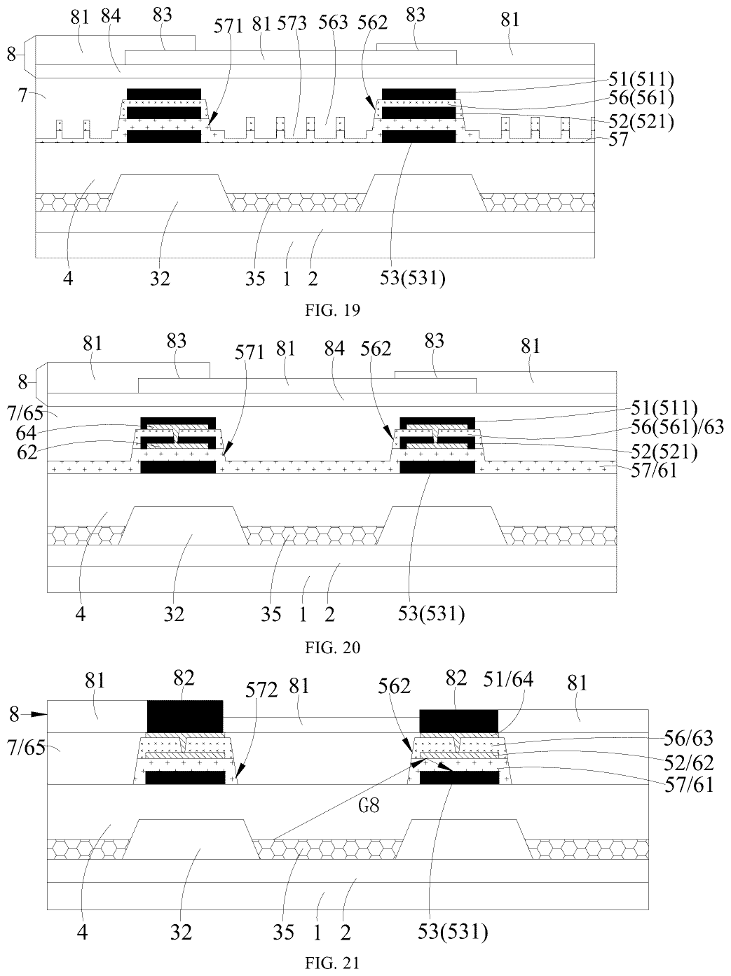

Furthermore, referring to FIG. 19, a plurality of first grooves 563 are provided on the first spacing layer 56, and an orthographic projection of a first groove 563 on the base substrate 1 at least partially overlaps with an orthographic projection of a second groove on the base substrate 1. In some embodiments, the first groove 563 and the second groove 573 may be formed by a same photolithography process, and therefore, the orthographic projection of the second groove 573 on the base substrate 1 may coincide with the orthographic projection of the first groove 563 on the base substrate 1. Certainly, when the first groove 563 and the second groove 573 are formed by different photolithography processes, a portion of the orthographic projection of the second groove 573 on the base substrate 1 may overlap with a portion of the orthographic projection of the first groove 563 on the base substrate 1, or the orthographic projection of the second groove 573 on the base substrate 1 may cover and be greater than the orthographic projection of the first groove 563 on the base substrate 1, or the orthographic projection of the first groove 563 on the base substrate 1 may cover and be greater than the orthographic projection of the second groove 573 on the base substrate 1.

In addition, similarly, the inclined light emitted from the sub-pixel 35 is emitted to the side wall of the first groove 563 and the side wall of the second groove 573. The side wall of the first groove 563 and the side wall of the second groove 573 reflect the light, so that the light is emitted from the front of the display panel as much as possible, and the light-emitting efficiency of the display panel is improved. Moreover, the bonding force between the second spacing layer 57 and the subsequently formed planarization layer 7 is improved through the first groove 563 and the second groove 573, thus avoiding the peeling between the planarization layer 7 and the second spacing layer 57, and improving the reliability of the product.

Referring to FIG. 19, the first groove 563 may be configured as a blind hole, the second groove 573 may be configured as a via hole, and the second groove 573 is communicated with the first groove 563. In some embodiments of the present disclosure, the first groove 563 may also be configured as a via hole, and the second groove 573 may also be configured as a blind hole. The blind hole is a hole connecting the surface layer and the inner layer without passing through the entire plate. The via is a hole connecting the surface layer and the inner layer and passing through the entire plate.

In some example embodiments of the present disclosure, as shown in FIG. 5, a touch layer group 6 may be provided on a side of the light-shielding layer group 5 away from the base substrate 1; a reflex reduction layer 91 may be provided on a side of the touch layer group 6 away from the base substrate 1; and a cover plate 92 may be provided on a side of the reflex reduction layer 91 away from the base substrate 1. The reflex reduction layer 91 may include a polarizer and a color film layer.

The touch layer group 6 may include a barrier layer 61, a first touch layer 62, a touch insulating layer 63, a second touch layer 64, and a protecting layer 65. The barrier layer 61 is provided on a side of the encapsulation layer group 4 away from the base substrate 1, and the material of the barrier layer 61 is generally a SiNx material. The first touch layer 62 is provided on a side of the barrier layer 61 away from the base substrate 1, and the first touch layer 62 may be of a three-layer structure such as Ti/Al/Ti, ITO/Ag/ITO, or the like. The touch insulating layer 63 is provided on a side of the first touch layer 62 away from the base substrate 1, and the material of the touch insulating layer 63 is generally a SiNx material. The second touch layer 64 is provided on a side of the touch insulating layer 63 away from the base substrate 1, and the second touch layer 64 may be of a three-layer structure such as Ti/Al/Ti, ITO/Ag/ITO, or the like. The protecting layer 65 is provided on a side of the second touch layer 64 away from the base substrate 1, and the material of the protecting layer 65 is PI (polyimide). Certainly, the materials and structures of the above-mentioned film layers are merely examples, and may also be selected according to requirements.

The touch layer group 6 may include touch wires, and the touch wires are connected to form a grid shape. In some embodiments, the first touch layer 62 includes first touch wires, and the first touch wires are connected to form a grid shape; the second touch layer 64 includes second touch wires, and the second touch wires are connected to form a grid shape. That is, the first touch layer 62 and the second touch layer 64 are configured as conductive grid structures. That is, the first touch layer 62 and the second touch layer 64 are a plurality of grids formed by interweaving a plurality of touch wires, and the grid is a polygon formed by a plurality of grid lines. One grid corresponds to one sub-pixel 35, and the orthographic projection of the sub-pixel 35 on the base substrate 1 is located within the orthographic projection of the grid on the base substrate 1, so that the grid line is prevented from shielding the light emitted by the sub-pixel 35, and the display effect of the display panel is ensured.

The light-shielding portion 502 covers at least a portion of the touch wires, or a portion of film layers of the touch layer group 6 is reused as a portion of film layers of the light-shielding layer group 5.

In some embodiments, referring to FIG. 20, a third light-shielding layer 53 is provided on a side of the encapsulation layer group 4 away from the base substrate 1, a barrier layer 61 is provided on a side of the third light-shielding layer 53 away from the base substrate 1, and the barrier layer 61 is reused as the second spacing layer 57. That is, the barrier layer 61 not only functions to isolate the first touch layer 62 from the encapsulation layer group 4, but also functions to isolate the third light-shielding layer 53 from the second light-shielding layer 52. In this way, the number of film layers is reduced, so that the display panel is lighter and thinner, and the display panel can be bent to be suitable for the bending display apparatus.

A first touch layer 62 is provided on a side of the barrier layer 61 away from the base substrate 1, a second light-shielding layer 52 is provided on a side of the first touch layer 62 away from the base substrate 1, and a second light-shielding portion 521 of the second light-shielding layer 52 covers at least a portion of the first touch wires. Since the first touch wires are provided on the periphery of each sub-pixel 35, and the second light-shielding portion 521 may only be provided on two opposite sides of the sub-pixel 35 along the second direction Y, in this case, the second light-shielding portion 521 of the second light-shielding layer 52 covers a portion of the first touch wires. Certainly, in some example embodiments, the second light-shielding portion 521 may also be provided on the periphery of the sub-pixel 35; in this case, the second light-shielding portion 521 of the second light-shielding layer 52 may completely cover the first touch wires. The second light-shielding portion 521 covers the first touch wires, which can reduce the reflection of light by the first touch wires, thus reducing the possibility of external imaging of the display panel, reducing the external visibility of the display panel, and further achieving peep-proof.

A touch insulating layer 63 is provided on a side of the second light-shielding layer 52 away from the base substrate 1, and the touch insulating layer 63 is reused as the first spacing layer 56. That is, the touch insulating layer 63 not only functions to isolate the first touch layer 62 from the second touch layer 64, but also functions to isolate the second light-shielding layer 52 from the first light-shielding layer 51. Therefore, the number of film layers is reduced, so that the display panel is lighter and thinner, and the display panel can be bent to be suitable for the bending display apparatus. A second touch layer 64 is provided on a side of the touch insulating layer 63 away from the base substrate 1.

A first light-shielding layer 51 is provided on a side of the second touch layer 64 away from the base substrate 1, and a first light-shielding portion 511 of the first light-shielding layer 51 covers at least a portion of the second touch wires. Since the second touch wires are provided on the periphery of each sub-pixel 35, and the first light-shielding portion 511 may only be provided on two opposite sides of the sub-pixel 35 along the second direction Y, in this case, the first light-shielding portion 511 of the first light-shielding layer 51 covers a portion of the second touch wires. In some embodiments, the first light-shielding portion 511 May also be provided on the periphery of the sub-pixel 35; in this case, the first light-shielding portion 511 of the first light-shielding layer 51 may completely cover the second touch wires. Similarly, the first light-shielding portion 511 covers the second touch wire, which can reduce the reflection of light by the second touch wire, thus reducing the possibility of external imaging of the display panel, reducing the external visibility of the display panel and further achieving peep-proof.

A protecting layer 65 is provided on a side of the first light-shielding layer 51 away from the base substrate 1, and the protecting layer 65 is reused as a planarization layer 7. That is, the protecting layer 65 functions to protect the second touch layer 64, and also functions to protect the first light-shielding layer 51. In this way, the number of the film layers is reduced, so that the display panel is lighter and thinner, and the display panel can be bent to be suitable for the bending display apparatus.

Furthermore, referring to FIG. 15 to FIG. 20, the display panel may further include a color film layer 8. The color film layer 8 may include a plurality of light-filtering portions 81. An overlapping portion 83 is provided between two adjacent light-filtering portions 81, and the colors of light to be filtered by the two adjacent light-filtering portions 81 are different. For example, it may be that a red light-filtering portion 81 overlaps with a blue light-filtering portion 81. Only red light can pass through the red light-filtering portion 81, and only blue light can pass through the blue light-filtering portion 81. Therefore, the red light passing through the red light-filtering portion 81 cannot pass through the blue light-filtering portion 81, and light cannot pass through the overlapping portion 83 of the color filter layer 8.

An orthographic projection of the overlapping portion 83 on the base substrate 1 at least partially overlaps with an orthographic projection of the light-shielding portion 502 on the base substrate 1, so as to avoid effect on the opening area of the sub-pixel 35 and effect on the light-emitting efficiency of the display panel. The overlapping portion 83 may also function to shield the inclined light, further achieving peep-proof and avoiding formation of an inverted image on the windshield when the display panel is used for the vehicle-mounted display apparatus.

In some embodiments of the present disclosure, referring to FIG. 21, a third light-shielding layer 53 is provided on a side of the encapsulation layer group 4 away from the base substrate 1. A barrier layer 61 is provided on a side of the third light-shielding layer 53 away from the base substrate 1, and the barrier layer 61 is reused as the second spacing layer 57. That is, the barrier layer 61 not only functions to isolate the first touch layer 62 from the encapsulation layer group 4, but also functions to isolate the third light-shielding layer 53 from the second light-shielding layer 52, so that the display panel can be bent to be suitable for the bending display apparatus.

A first touch layer 62 is provided on a side of the barrier layer 61 away from the base substrate 1, and the first touch layer 62 is reused as the second light-shielding layer 52. That is, the first touch layer 62 not only functions to sense a touch signal, but also functions to shield emission of the light with a relatively larger inclination angle. In addition, the number of film layers can be reduced, so that the display panel is lighter and thinner, and the display panel can be bent to be suitable for the bending display apparatus.

A touch insulating layer 63 is provided on a side of the first touch layer 62 away from the base substrate 1, and the touch insulating layer 63 is reused as the first spacing layer 56. That is, the touch insulating layer 63 not only functions to isolate the first touch layer 62 from the second touch layer 64, but also functions to isolate the second light-shielding layer 52 from the first light-shielding layer 51. In addition, the number of film layers can be reduced, so that the display panel is lighter and thinner, and the display panel can be bent to be suitable for the bending display apparatus.

A second touch layer 64 is provided on a side of the touch insulating layer 63 away from the base substrate 1. The second touch layer 64 is reused as the first light-shielding layer 51. That is, the second touch layer 64 not only functions to sense a touch signal, but also functions to shield emission of the light with a relatively larger inclination angle. In addition, the number of film layers can be reduced, so that the display panel is lighter and thinner, and the display panel can be bent to be suitable for the bending display apparatus.

A protecting layer 65 is provided on a side of the second touch layer 64 away from the base substrate 1, and the protecting layer 65 is reused as a planarization layer 7. Therefore, the number of film layers is reduced, so that the display panel is lighter and thinner, and the display panel can be bent. In addition, the protecting layer 65 may not cover the second touch layer 64, but fill the via holes in the second touch layer 64, that is, to fill the sub-pixels 35 and achieve a planarization effect, thus providing a relatively flat basic plane for the subsequent formation of the color film layer 8.

In some embodiments of the present disclosure, the protecting layer 65 may not only fill the via holes in the second touch layer 64, but also cover the second touch layer 64. The second touch layer 64 is protected through the protecting layer 65, thus avoiding short circuit of the second touch layer 64 due to being connected to other devices.

Furthermore, the display panel may further include a color film layer 8 provided on a side of the light-shielding layer group 5 away from the base substrate 1. In some embodiments, the color film layer 8 is provided on a side of the protecting layer 65 away from the base substrate 1. The color film layer 8 may include a base layer 84, a plurality of light-filtering portions 81 and light-blocking portions 82 provided on a side of the base layer 84. In some embodiments, the base layer 84 may not be provided. A light-blocking portion 82 is provided between two adjacent light-filtering portions 81, and the light-blocking portion 82 is located on a side of the second touch layer 64 away from the base substrate 1. The orthographic projection of the light-blocking portion 82 on the base substrate 1 at least partially overlaps with the orthographic projection of the second touch layer 64 on the base substrate 1; for example, the light-blocking portion 82 may cover the second touch layer 64. The light-blocking portion 82 covers the second touch layer 64, which can reduce the reflection of light by the second touch layer 64 and the first touch layer 62, thus reducing the possibility of external imaging of the display panel, reducing the external visibility of the display panel, further achieving peep-proof, and avoiding formation of an inverted image on the windshield when the display panel is used for the vehicle-mounted display apparatus.

Moreover, the orthographic projection of the light-blocking portion 82 on the base substrate 1 at least partially overlaps with the orthographic projection of the light-shielding portion 502 on the base substrate 1, thus avoiding effect on the opening area of the sub-pixel 35 and effect on the light-emitting efficiency of the display panel.

In addition, in the case that the first touch layer and the second touch layer are reused as light-shielding layers, although the first touch layer and the second touch layer are not able to absorb light, the first touch layer and the second touch layer are able to reflect the light G8 to the third light-shielding layer 53, so that the light is absorbed by the third light-shielding layer 53 and is prevented from being emitted, thus achieving the purpose of peep-proof and avoiding the formation of an inverted image on the windshield.

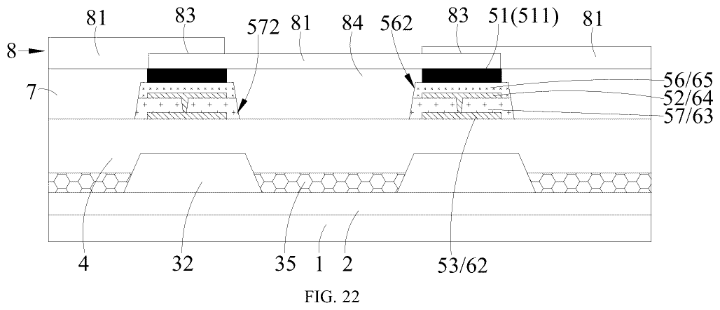

In some embodiments of the present disclosure, referring to FIG. 22, a first touch layer 62 is provided on a side of the encapsulation layer group 4 away from the base substrate 1, and the first touch layer 62 is reused as a third light-shielding layer 53. That is, the first touch layer 62 not only functions to sense a touch signal, but also functions to shield emission of the light with a relatively larger inclination angle. In addition, the number of film layers can be reduced, so that the display panel is lighter and thinner, and the display panel can be bent to be suitable for the bending display apparatus.

A touch insulating layer 63 is provided on the side of the first touch layer 62 away from the base substrate 1, and the touch insulating layer 63 is reused as a second spacing layer 57. That is, the touch insulating layer 63 not only functions to isolate the first touch layer 62 from the second touch layer 64, but also functions to isolate the third light-shielding layer 53 from the second light-shielding layer 52. In addition, the number of film layers can be reduced, so that the display panel is lighter and thinner, and the display panel can be bent to be suitable for the bending display apparatus.

A second touch layer 64 is provided on a side of the touch insulating layer 63 away from the base substrate 1. The second touch layer 64 is reused as a second light-shielding layer 52. That is, the second touch layer 64 not only functions to sense a touch signal, but also functions to shield emission of the light with a relatively larger inclination angle. In addition, the number of film layers can be reduced, so that the display panel is lighter and thinner, and the display panel can be bent to be suitable for the bending display apparatus.

A protecting layer 65 is provided on a side of the second touch layer 64 away from the base substrate 1, and the protecting layer 65 is reused as a first spacing layer 56. Therefore, the number of film layers can be reduced, so that the display panel is lighter and thinner, and the display panel can be bent.

A first light-shielding layer 51 is provided on a side of the protective layer 65 away from the base substrate 1, and the first light-shielding layer 51 comprises a first light-shielding portion 511. The orthographic projection of the first light-shielding portion 511 on the base substrate 1 at least partially overlaps with the orthographic projection of the first touch layer 62 on the base substrate 1 and the orthographic projection of the second touch layer 64 on the base substrate 1, so that the first light-shielding layer 51 can shield the first touch layer 62 and the second touch layer 64, which can reduce the reflection of light by the second touch layer 64 and the first touch layer 62, thus reducing the possibility of external imaging of the display panel, reducing the external visibility of the display panel, further achieving peep-proof, and avoiding the formation of an inverted image on the windshield when the display panel is used for the vehicle display apparatus.

A planarization layer 7 is provided on a side of the first light-shielding layer 51 away from the base substrate 1. The planarization layer 7 may not cover the first light-shielding layer 51, but fill the via holes in the first light-shielding layer 51, that is, to fill the sub-pixels 35 and achieve a planarization effect, thus providing a relatively flat basic plane for the subsequent formation of the color film layer 8.

In some embodiments of the present disclosure, the planarization layer 7 may not only fill the via holes in the first light-shielding layer 51, but also cover the first light-shielding layer 51. The first light-shielding layer 51 is protected through the protecting layer 65.

Furthermore, the display panel may further include a color film layer 8. The color film layer 8 may include a plurality of light-filtering portions 81. An overlapping portion 83 is provided between two adjacent light-filtering portions 81, and the colors of light to be filtered by the two adjacent light-filtering portions 81 are different. For example, it may be that a red light-filtering portion 81 overlaps with a blue light-filtering portion 81. Only red light can pass through the red light-filtering portion 81, and only blue light can pass through the blue light-filtering portion 81. Therefore, the red light passing through the red light-filtering portion 81 cannot pass through the blue light-filtering portion 81, and light cannot pass through the overlapping portion 83 of the color filter layer 8.

An orthographic projection of the overlapping portion 83 on the base substrate 1 at least partially overlaps with an orthographic projection of the light-shielding portion on the base substrate 1, so as to avoid effect on the opening area of the sub-pixel 35 and effect on the light-emitting efficiency of the display panel. The overlapping portion 83 may also function to shield the inclined light, further achieving peep-proof and avoiding formation of an inverted image on the windshield when the display panel is used for the vehicle-mounted display apparatus.

Moreover, the ambient light that is reflected by the front windshield and enters the display panel, may be absorbed by the color film layer 8 and the light-shielding layer group 5, thus improving the stability of vehicle-mounted display.

Furthermore, referring to FIG. 21 and FIG. 22, a plurality of second via holes 572 are provided on the second spacing layer. An orthographic projection of a second via hole 572 on the base substrate at least partially overlaps with an orthographic projection of the sub-pixel on the base substrate. For example, it may be that the orthographic projection of the second via hole 572 on the base substrate 1 covers and is greater than the orthographic projection of the sub-pixel 35 on the base substrate 1, or a portion of the orthographic projection of the second via hole 572 on the base substrate 1 overlaps with a portion of the orthographic projection of the sub-pixel 35 on the base substrate 1, or the orthographic projection of the sub-pixel 35 on the base substrate 1 covers and is greater than the orthographic projection of the second via hole 572 on the base substrate 1. In this way, at least a portion of the front light-emitting side of the sub-pixel 35 is not covered by the second spacing layer, so as to avoiding effect on the front light-emitting efficiency of the display panel due to the fact that the light emitted from the front of the sub-pixel 35 is reflected at the interface between the second spacing layer 57 and the planarization layer.

Based on the same inventive concept, there is provided a display apparatus according to example embodiments of the present disclosure. The display apparatus may include the above-mentioned display panel, the specific structure of the display panel has been described in detail above, and therefore, details are not described here again. The display apparatus may be a vehicle-mounted display apparatus. In addition to the display panel, the display apparatus further includes other necessary components and compositions, such as a housing, a circuit board, a power line, etc., on which those skilled in the art may make a corresponding supplement according to the specific use requirements of the display apparatus, and details are not described here again.

Other embodiments of the present disclosure will be apparent to those skilled in the art from consideration of the description and practice of the present disclosure here. The present disclosure is intended to cover any variations, uses, or adaptations of the present disclosure following the general principles of the present disclosure and including common general knowledge or conventional technical means in the art not disclosed in the present disclosure. The description and embodiments may be considered as examples only, with a true scope and spirit of the disclosure being indicated by the appended claims.

1. A display panel, comprising:
a base substrate;
a light-emitting substrate, provided on a side of the base substrate, wherein the light-emitting substrate comprises a plurality of sub-pixels; and
a light-shielding layer group, provided on a side of the light-emitting substrate away from the base substrate, wherein the light-shielding layer group comprises at least two light-shielding layers, a light-shielding layer comprises a plurality of light-shielding portions, an orthographic projection of a light-shielding portion of each of the light-shielding layers on the base substrate at least partially overlaps with each other, and the orthographic projection of the light-shielding portion on the base substrate does not overlap with an orthographic projection of a sub-pixel on the base substrate.

2. The display panel according to claim 1, wherein a distance between two adjacent light-shielding layers increases as a distance between a light-shielding layer close to or far away from the base substrate and the base substrate increases.

3. The display panel according to claim 2, wherein the light-shielding portion is located on at least one side of the sub-pixel along a second direction, the second direction is a peep-proof direction, and the second direction is parallel to a surface of the base substrate close to the light-emitting substrate.

4. The display panel according to claim 3, wherein the plurality of sub-pixels comprise a first sub-pixel, a second sub-pixel, and a third sub-pixel with different colors; a plurality of first sub-pixels and a plurality of second sub-pixels are alternately arranged along a first direction to form a first pixel row, a plurality of third sub-pixels are arranged along the first direction to form a second pixel row, a plurality of first pixel rows and a plurality of second pixel rows are alternately arranged along the second direction, and a gap is provided between the first pixel row and the second pixel row; the light-shielding portion is configured as a strip shape extended along the first direction, and the orthographic projection of the light-shielding portion on the base substrate at least partially overlaps with an orthographic projection of the gap on the base substrate;
the first direction is parallel to the surface of the base substrate close to the light-emitting substrate, and the first direction intersects with the second direction.

5. The display panel according to claim 4, wherein the first sub-pixel, the second sub-pixel, and the third sub-pixel are provided with a same width in the second direction.

6. The display panel according to claim 3, wherein the light-shielding layer group comprises five light-shielding layers, comprising a first light-shielding layer, a second light-shielding layer, a third light-shielding layer, a fourth light-shielding layer and a fifth light-shielding layer sequentially arranged in a direction from the light-emitting substrate to the base substrate; the first light-shielding layer comprises a plurality of first light-shielding portions, the second light-shielding layer comprises a plurality of second light-shielding portions, the third light-shielding layer comprises a plurality of third light-shielding portions, the fourth light-shielding layer comprises a plurality of fourth light-shielding portions, and the fifth light-shielding layer comprises a plurality of fifth light-shielding portions; an orthographic projection of a first light-shielding portion, an orthographic projection of a second light-shielding portion, an orthographic projections of a third light-shielding portion, an orthographic projection of a fourth light-shielding portion, and an orthographic projection of a fifth light-shielding portion on the base substrate overlap with each other;
wherein a distance between a light-shielding layer farthest away from the light-emitting substrate and the sub-pixel is Z1; and
$$Z 1 = A / tan θ$$
wherein θ is a peep-proof viewing angle, and A is a width of the sub-pixel in the second direction;
a distance between the first light-shielding layer and the second light-shielding layer is Z2, and Z2=Z1×B(B+A): a distance between the second light-shielding layer and the third light-shielding layer is Z3, and Z3=(Z1−Z2)×B(B+A): a distance between the third light-shielding layer and the fourth light-shielding layer is Z4, and Z4=(Z1−Z2−Z3)×B(B+A): a distance between the fourth light-shielding layer and the fifth light-shielding layer is Z5, and Z5=(Z1−Z2−Z3−Z4)×B(B+A);
wherein B is a width of the first light-shielding portion in the second direction; and
a distance between a light-shielding layer closest to the light-emitting substrate and the sub-pixel is Z6:
$$Z 6 = ( A + B ) tan β ,$$
wherein β is a critical angle; the light-shielding layer is not needed to be provided for shielding light with an angle greater than the critical angle; and B is the width of the first light-shielding portion in the second direction.

7-9. (canceled)

10. The display panel according to claim 1, wherein a thickness of the light-shielding layer is greater than or equal to 1 μm and less than or equal to 3 m; and
the display panel further comprises:
an encapsulation layer group, provided on a side of the light-emitting substrate away from the base substrate, wherein at least a portion of a film layer of the encapsulation layer group is reused as the light-shielding layer group, or the encapsulation layer group is provided between the light-emitting substrate and the light-shielding layer group.

11. (canceled)

12. The display panel according to claim 1, wherein the light-shielding layer group further comprises at least two spacing layers, and a spacing layer is provided between two adjacent light-shielding layers.

13. The display panel according to claim 12, wherein the light-shielding layer group comprises three light-shielding layers, comprising a first light-shielding layer, a second light-shielding layer and a third light-shielding layer sequentially arranged in a direction from the light-emitting substrate to the base substrate; the first light-shielding layer comprises a plurality of first light-shielding portions, the second light-shielding layer comprises a plurality of second light-shielding portions, and the third light-shielding layer comprises a plurality of third light-shielding portions; an orthographic projection of a first light-shielding portion, an orthographic projection of a second light-shielding portion, and an orthographic projection of a third light-shielding portion on the base substrate overlap with each other; and the at least two spacing layers comprises:
a first spacing layer, provided between the first light-shielding layer and the second light-shielding layer; and
a second spacing layer, provided between the second light-shielding layer and the third light-shielding layer, wherein a refractive index of the first spacing layer is less than or equal to a refractive index of the second spacing layer.

14. The display panel according to claim 13, wherein a plurality of second protrusion portions are provided on a surface of the second spacing layer away from the base substrate, and an orthographic projection of a second protrusion portion on the base substrate covers and is greater than an orthographic projection of a third light-shielding portion on the base substrate; and the first spacing layer comprises a plurality of first protrusion portions, and a first protrusion portion covers a second light-shielding portion;
a plurality of first via holes are provided on the first spacing layer, and an orthographic projection of a first via hole on the base substrate at least partially overlaps with the orthographic projection of the sub-pixel on the base substrate; and
a plurality of second via holes are provided on the second spacing layer, and an orthographic projection of a second via hole on the base substrate at least partially overlaps with the orthographic projection of the sub-pixel on the base substrate.

15-16. (canceled)

17. The display panel according to claim 13, wherein a plurality of second grooves are provided on the second spacing layer, and an orthographic projection of a second groove on the base substrate at least partially overlaps with the orthographic projection of the sub-pixel on the base substrate.

18. The display panel according to claim 17, wherein a plurality of first grooves are provided on the first spacing layer, and an orthographic projection of a first groove on the base substrate at least partially overlaps with the orthographic projection of the second groove on the base substrate; and
the first groove is a blind hole, the second groove is a via hole, and the second groove is communicated with the first groove.

19. (canceled)

20. The display panel according to claim 13, wherein the display panel further comprises:
a planarization layer, provided on a side of the light-shielding layer group away from the base substrate, wherein a refractive index of the planarization layer is greater than the refractive index of the second spacing layer; and
a touch layer group, provided on a side of the light-emitting substrate away from the base substrate, wherein the touch layer group comprises touch wires, the touch wires are connected to form a grid shape, the light-shielding portion covers at least a portion of the touch wires, or a portion of a film layer of the touch layer group is reused as a portion of a film layer of the light-shielding layer group.

21. (canceled)

22. The display panel according to claim 20, wherein the touch layer group comprises:
a barrier layer, provided on a side of the light-emitting substrate away from the base substrate;
a first touch layer, provided on a side of the barrier layer away from the base substrate, wherein the first touch layer comprises first touch wires, and the first touch wires are connected to form a grid shape;
a touch insulating layer, provided on a side of the first touch layer away from the base substrate;
a second touch layer, provided on a side of the touch insulating layer away from the base substrate, wherein the second touch layer comprises second touch wires, and the second touch wires are connected to form a grid shape; and
a protecting layer, provided on a side of the second touch layer away from the base substrate.

23. The display panel according to claim 22, wherein the barrier layer is reused as the second spacing layer, the second light-shielding portion covers at least a portion of the first touch wires, the touch insulating layer is reused as the first spacing layer, the first light-shielding portion covers at least a portion of the second touch wires, and the protecting layer is reused as the planarization layer.

24. The display panel according to claim 22, wherein the barrier layer is reused as the second spacing layer, the first touch layer is reused as the second light-shielding layer, the touch insulating layer is reused as the first spacing layer, and the second touch layer is reused as the first light-shielding layer.

25. The display panel according to claim 22, wherein the first touch layer is reused as the third light-shielding layer, the touch insulating layer is reused as the second spacing layer, the second touch layer is reused as the second light-shielding layer, and the protecting layer is reused as the first spacing layer.

26. The display panel according to claim 1, wherein the display panel further comprises:
a color film layer, provided on a side of the light-shielding layer group away from the base substrate, wherein the color film layer comprises a plurality of light-filtering portions, an overlapping portion is provided between two adjacent light-filtering portions, and an orthographic projection of the overlapping portion on the base substrate at least partially overlaps with the orthographic projection of the light-shielding portion on the base substrate.

27. The display panel according to claim 1, wherein the display panel further comprises:
a color film layer, provided on a side of the light-shielding layer group away from the base substrate, wherein the color film layer comprises a plurality of light-filtering portions and a light-blocking portion, the light-blocking portion is provided between two adjacent light-filtering portions, and an orthographic projection of the light-blocking portion on the base substrate at least partially overlaps with the orthographic projection of the light-shielding portion on the base substrate.

28. A display apparatus, comprising a display panel, wherein the display panel comprises:
a base substrate;
a light-emitting substrate, provided on a side of the base substrate, wherein the light-emitting substrate comprises a plurality of sub-pixels; and
a light-shielding layer group, provided on a side of the light-emitting substrate away from the base substrate, wherein the light-shielding layer group comprises at least two light-shielding layers, a light-shielding layer comprises a plurality of light-shielding portions, an orthographic projection of a light-shielding portion of each of the light-shielding layers on the base substrate at least partially overlaps with each other, and the orthographic projection of the light-shielding portion on the base substrate does not overlap with an orthographic projection of a sub-pixel on the base substrate.
